(19) United States
(12) Patent Application Publication
(10) Pub. No.: US 2025/0331105 A1
(43) Pub. Date: Oct. 23, 2025

(54) CIRCUIT ARRANGEMENT

(71) Applicant: Continental Autonomous Mobility Germany GmbH, Ingolstadt (DE)

(72) Inventors: Peter Fritsche, Tettnang (DE); Tobias Koppe, Wangen im Allgaeu (DE); Dieter Ehrmann, Lindau (DE)

(73) Assignee: Continental Autonomous Mobility Germany GmbH, Ingolstadt (DE)

(21) Appl. No.: 19/181,686

(22) Filed: Apr. 17, 2025

(30) Foreign Application Priority Data
Apr. 18, 2024 (DE) 10 2024 203 627.7

(51) Int. Cl. H05K 1/18; G01S 7/03

(52) U.S. Cl. CPC H05K 1/18; G01S 7/032; H05K 2201/10022; H05K 2201/10098; H05K 2201/10522; H05K 2201/10537

(57) ABSTRACT

A circuit arrangement for capturing a position change of a component, comprising a printed circuit board. The component comprises a component portion with which the component is arranged on the printed circuit board and is aligned therewith. At least one movement direction is provided, in which the component moves in the event of a position change. At least one resistor is arranged in the movement direction with a tolerance distance from the component portion such that, in the event of a position change of the component, the tolerance distance is exceeded so that the component portion shears the resistor.

### TECHNICAL FIELD

The present embodiments relate to a circuit arrangement as well as a corresponding device, in particular a surroundings capturing sensor, radar sensor or control apparatus, comprising a circuit arrangement as well as a vehicle which has such a device.

### BACKGROUND

In modern motor vehicles or motorcycles, sensor systems such as, e.g., radar sensors, lidar sensors, camera sensors or the like are increasingly deployed in order to capture the surroundings. Conclusions can subsequently be drawn about the surroundings from the sensor data determined by the sensors. The capturing of the surroundings by means of radar sensors is based on the emission of bundled electromagnetic waves and the reflection thereof, e.g., by other road users, obstacles on the road or the peripheral development of the road. Radar sensors can be deployed, including in fusion with other technology's sensors such as, e.g., camera or lidar sensors, for systems of the type described above. One of the advantages of radar sensors is that they work reliably, even in poor weather conditions, and, in addition to the distance of objects, they can also directly measure the radial relative speed thereof by means of the Doppler effect. As a general rule, 24 GHz, 77 GHz and 79 GHz are deployed as transmitting frequencies. Due to the increasing functional scope of such systems, the requirements, in particular in terms of the maximum detection range, are constantly increasing. In addition to capturing the surroundings of motor vehicles for systems of the type described above, the focus is now also turning toward monitoring the interior of motor vehicles, e.g., in order to recognize which seats are occupied; e.g., frequencies in the range of 60 GHz are deployed.

However, generic radar sensors can have a misalignment or a faulty fitting of the antenna due to the incorrect mounting or installation on the vehicle. For example, in the case of modern radar sensors, it must be ensured that the antenna is precisely positioned on the printed circuit board in order to guarantee the correct function of the radar. During a shift, the signal path is attenuated, the range and the target recognition are reduced. As a result, the required function of the radar can be massively restricted without the system noticing the restriction, which can then lead to performance losses and safety-critical behavior of the system. Thus, there is an increased interest in reliably recognizing such shifts.

The prior art discloses a control unit for a vehicle, which comprises a printed circuit board on which electronic components are arranged. The control unit has a manipulation protection mechanism, by means of which the components on the printed circuit board and/or the printed circuit board itself can be damaged or destroyed. The damage to the components can comprise all of the components of the printed circuit board or only a part of the components of the printed circuit board and/or the printed circuit board itself. In this context, the damage is to be understood to mean that the components sustain damage which prevents the proper functioning of the components and, consequently, prevents re-commissioning. The components are destroyed by the damage and/or are no longer operational. The fact that the components on the printed circuit board no longer function properly means that a manipulation from outside is prevented when an attempt is made to open the control unit. To this end, a shearing device is provided, wherein the components on the printed circuit board are sheared or destroyed by means of the shearing device when the control unit is opened incorrectly.

Therefore, the problem consists of making available a device or a method with which a position change or misalignment of components such as, e.g., of the antenna of a radar sensor, is prevented or recognized, so that operative readiness continues to be guaranteed or the sensor is safely deactivated.

### SUMMARY

The aforementioned problem is solved by a misalignment of components such as, e.g., of the antenna of the radar sensor, being prevented or recognized so that the sensor remains operational or, in the event of a malfunction, is permanently switched off when it is no longer operational.

The circuit arrangement for capturing a position change of a component comprises at least one printed circuit board, wherein the component comprises a component portion with which the component is arranged on the printed circuit board and is aligned therewith. Furthermore, at least one movement direction is provided, in which the component moves in the event of a position change. In this case, at least one resistor is arranged in the movement direction with a tolerance distance from the component portion such that in the event of a position change or shift of the component, the tolerance distance is exceeded so that the component portion shears the resistor in that the resistor can no longer retain the component against shifting, so that the resistor is destroyed by the movement and the line is open. Consequently, a position change or misalignment of a component on the printed circuit board can be recognized automatically, so that the operative readiness remains guaranteed or the sensor is safely deactivated. In this case, an additional shearing device is not needed. Furthermore, the user can be informed immediately, e.g., during operation or in a manufacturing step as soon as a resistor has sheared.

According to a configuration, multiple movement directions can be provided, in particular two opposing movement directions, four movement directions arranged in a cross-shaped manner or eight movement directions. In a practical way, all shearing or movement directions can be covered as a result, so that the recognition of a position change can be carried out even more reliably.

Multiple resistors can be expediently provided, wherein at least one resistor is arranged around the component portion in each case in a movement direction.

The resistance value of the resistor(s) is for example less than 1 ohm, e.g. 0 ohm.

According to a embodiment, the component is an antenna. For example, it can be an at least partially metallized plastic antenna of a radar sensor.

The printed circuit board has at least one passage or one opening, via which the component portion of the component, with which the component is arranged on the printed circuit board and is aligned therewith, is arranged.

The resistor or the resistors may be part of a voltage supply or part of a power supply unit, wherein the function of the voltage supply or of the power supply unit is switched off or adversely affected due to the line opening in the event of a position change and resistor(s) shearing.

The resistors can be expediently connected in series.

Furthermore, the embodiments also comprise a device, for example a sensor or radar sensor, which is preferably utilized for capturing the surroundings for a vehicle, or a control apparatus for a vehicle, which has a circuit arrangement. The component can be an antenna, for example an at least partially metallized plastic antenna. In this case, the radar chip can be arranged or soldered on a side of the printed circuit board, which in turn radiates through at least one opening or one passage of the printed circuit board into the component portion or component base of the antenna, with which the plastic antenna is arranged on the other side of the printed circuit board.

In addition, in an alternative, in a vehicle which comprises a device according to the embodiments is also described.

### BRIEF DESCRIPTION OF THE DRAWINGS

The invention is explained in greater detail below with reference to expedient exemplary embodiments, wherein:

FIG. 1 shows a simplified 3D representation of a configuration of a circuit arrangement;

FIG. 2 shows a simplified top view representation of a configuration of the printed circuit board of the circuit arrangement from FIG. 1;

FIG. 3 shows a simplified top view representation of a configuration of the printed circuit board with antenna base of the circuit arrangement from FIG. 1;

FIG. 4 shows a simplified top view representation of a configuration of the printed circuit board with antenna base of the circuit arrangement from FIG. 3 and marked movement directions;

FIG. 5 shows a simplified top view representation of a configuration of the printed circuit board with antenna base of the circuit arrangement from FIG. 3 and marked movement directions;

FIG. 6 shows a simplified representation of a configuration of a part of the circuit arrangement, and

FIG. 7 shows a simplified schematic representation of a configuration of a vehicle.

### DETAILED DESCRIPTION

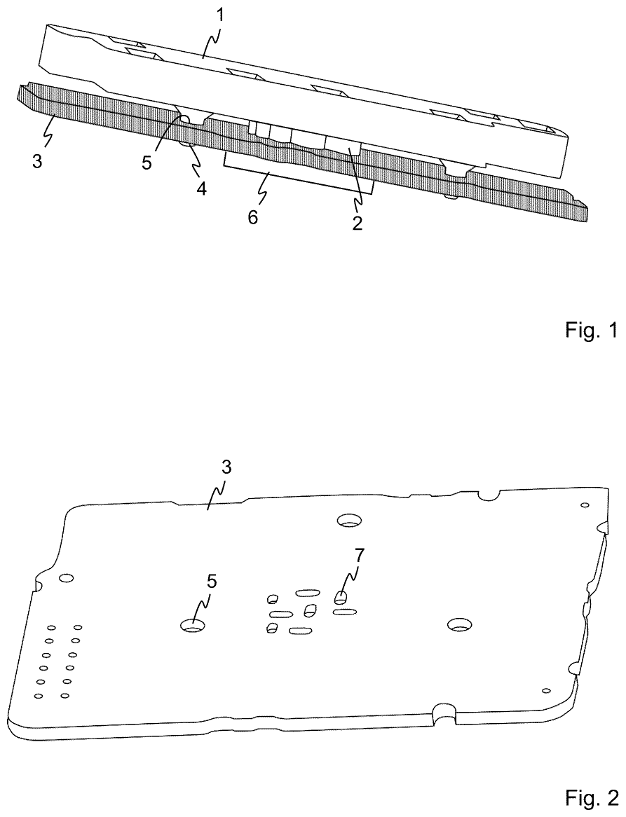

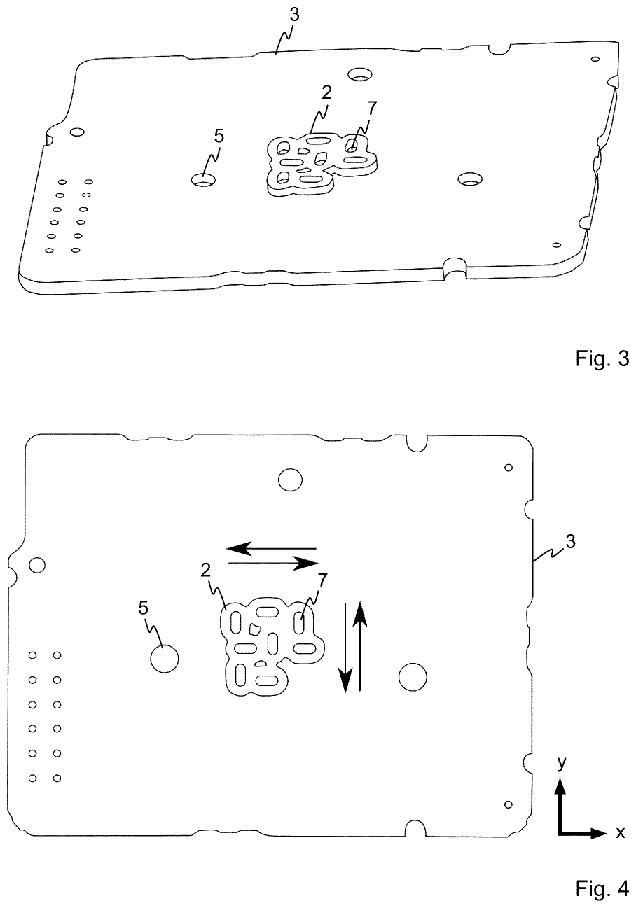

The circuit arrangement provides that resistors having a low resistance value, in particular 0-ohm resistors, on the printed circuit board or circuit board can be positioned around the contact region between the printed circuit board and the component. A circuit arrangement according to the invention is shown in FIGS. 1-3, which is part of a radar sensor. In this case, an antenna 1, which is arranged with a component portion or the antenna base 2 in an antenna contact region on the printed circuit board 3, is provided as a component. Furthermore, the antenna 1 can have additional fastening devices 4, with which the antenna 1 can be additionally fastened to the printed circuit board 3, e.g., in bores 5. The antenna 1 is an at least partially metallized plastic antenna, wherein the radar chip 6 can be arranged or soldered on one side of the printed circuit board, which in turn radiates through at least one opening or one passage 7 of the printed circuit board 3 into the component portion or antenna base 2 of the antenna, with which the antenna 1 is arranged on the other side of the printed circuit board 3.

A top view of the printed circuit board 3 is shown in FIG. 4, in which movement directions are now fixed with reference to black arrows, in which the antenna 1 or the antenna base 2 can move or be shifted. Of course, the antenna 1 can also shift in a direction which lies between these movement directions which would, however, also be captured up to a certain extent since a movement in an offset direction would also cause a movement in one of the fixed movement directions due to the dimensions of the antenna base. As a function of the geometry of the component or of the antenna 1 or of the antenna base 2, it is consequently fixed how many movement directions are required. In this case, multiple movement directions can be provided, for example two opposing movement directions, four movement directions arranged in a cross-shaped manner or eight movement directions or another resulting arrangement of movement directions around the component. As a result, all shearing or movement directions can be covered as a function of the geometry of the component, so that the recognition of a position change can be reliably carried out.

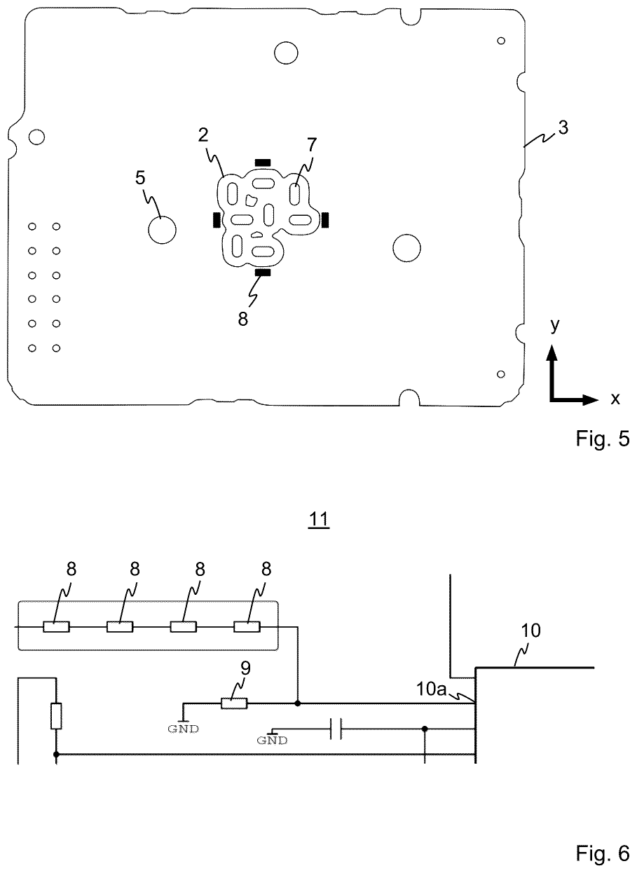

To this end, an arrangement of resistors 8, as shown in FIG. 5, which are arranged at a distance or tolerance distance, which includes a certain movement tolerance allowed for the function, from the component or from the antenna 1 or antenna base 2 in the direction of movement. Furthermore, multiple resistors 8 can be provided, wherein at least one resistor is arranged around the component portion or antenna base 3 in each case in a movement direction. These resistors 8 may be part of the power supply or of the power supply unit of the radar sensor so that the activate device or the “Enable pin” of the power supply unit can be controlled as long as the resistors 8 are present or operational. As soon as the component or the antenna moves more than is permissible, i.e., exceeds the tolerance distance, at least one of the resistors 8 is sheared, which then leads to an interruption in the power supply or in the power supply unit 11. In this case, a so-called “pull-down resistor” 9 at the “Enable pin” 10a of the IC module 10a of the power supply unit 11 leads to the power supply unit 11 of the radar sensor remaining permanently switched off.

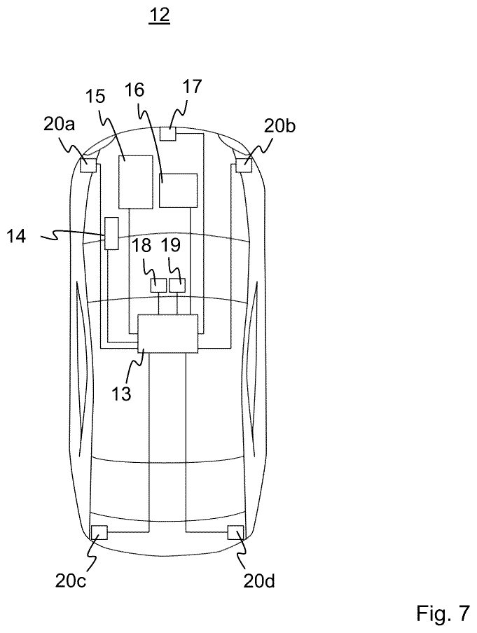

Reference numeral 12 in FIG. 7 denotes a vehicle which has a control apparatus 13, various actuators as well as sensors for capturing the surroundings. The vehicle 12 can be controlled in a partially automated manner in that the control apparatus 13 can access the actuators and the sensors or the sensor data thereof. In the field of assisted or automated driving, the sensor data can be utilized for recognizing the environment and objects so that various assistants or assistance functions such as, e.g., Adaptive Cruise Control, Electronic Brake Assist, a Lane Departure Warning System or a Lane Keep Assist (LKA), parking assistant, traffic jam assistant or the like, can be realized via the control apparatus 13 or the algorithm stored therein. Furthermore, the radar sensors 17 or 20a-20d can, for example, be radar sensors which have a circuit arrangement according to the invention. In the same way, the remaining sensors or the control apparatus 13 can admittedly also have a circuit arrangement, in which a component is arranged with a component portion on a printed circuit board and is aligned therewith, and at least one movement direction is provided, in which the component can move in the event of a position change, and at least one or multiple, resistor or resistors is/are arranged in the movement direction with a tolerance distance from the component portion such that, in the event of a position change of the component, the tolerance distance is exceeded so that the component portion initially contacts the resistor and then, in the course of the further movement of the component portion, shears or destroys the resistor since the resistor can no longer retain the component or the antenna or the component portion against shifting.

1. A circuit arrangement for capturing a position change of a component comprising:
a printed circuit board;
a component arranged on and aligned with the printed circuit board with a component portion, wherein in the event of a position change, the component moves in at least one movement direction; and
at least one resistor arranged one the printed circuit board in the movement direction with a tolerance distance from the component portion such that, in the event of a position change of the component, the tolerance distance is exceeded so that the component portion shears the resistor.

2. The circuit arrangement according to claim 1, wherein the at least one movement direction is multiple movement directions.

3. The circuit arrangement according to claim 2, wherein the multiple movement directions are one of two, four or eight movement directions.

4. The circuit arrangement according to claim 2, wherein the at least one resistor is multiple resistors, each arranged around the component portion in one of the multiple movement directions.

5. The circuit arrangement according to claim 4, wherein there are multiple resistors in each of the multiple movement directions.

6. The circuit arrangement according to claim 4, wherein the multiple resistors are connected in series.

7. The circuit arrangement according to claim 1, wherein the resistance value of the at least one resistor is less than 1 ohm.

8. The circuit arrangement according to claim 7, wherein the resistance value of the at least one resistor is 0 ohm.

9. The circuit arrangement according to claim 1, wherein the component is an antenna.

10. The circuit arrangement according to claim 1, wherein the antenna is an at least partially metallized plastic antenna.

11. The circuit arrangement according to claim 1, wherein the printed circuit board defines at least one passage via which the component portion is arranged on and aligned with the printed circuit board.

12. The circuit arrangement according to claim 1, wherein the function of the voltage supply or of the power supply unit is switched off or adversely affected in the event of a position change of the component, if the resistor or at least one of the resistors is sheared.

13. A radar sensor for capturing the surroundings for a vehicle, having a circuit arrangement for capturing a position change of the vehicle comprising:
a printed circuit board;
a component arranged on and aligned with the printed circuit board with a component portion, wherein in the event of a position change, the component moves in at least one movement direction; and
at least one resistor arranged one the printed circuit board in the movement direction with a tolerance distance from the component portion such that, in the event of a position change of the component, the tolerance distance is exceeded so that the component portion shears the resistor.

14. A vehicle comprising:
a radar sensor for capturing the surroundings for a vehicle having a circuit arrangement comprising:
a printed circuit board;
a component arranged on and aligned with the printed circuit board with a component portion, wherein in the event of a position change, the component moves in at least one movement direction; and
at least one resistor arranged one the printed circuit board in the movement direction with a tolerance distance from the component portion such that, in the event of a position change of the component, the tolerance distance is exceeded so that the component portion shears the resistor.
